(19) United States
(12) Patent Application Publication
(10) Pub. No.: US 2013/0163195 A1
(43) Pub. Date: Jun. 27, 2013

(54) SYSTEM, METHOD, AND COMPUTER PROGRAM PRODUCT FOR PERFORMING OPERATIONS ON DATA UTILIZING A COMPUTATION MODULE

(71) Applicant: Sean Michael Pelletier, Austin, TX (US)

(72) Inventor: Sean Michael Pelletier, Austin, TX (US)

(73) Assignee: NVIDIA CORPORATION, Santa Clara, CA (US)

(21) Appl. No.: 13/335,850

(22) Filed: Dec. 22, 2011

(51) Int. Cl. H05K 7/00

(52) U.S. Cl. 361/679.55

(57) ABSTRACT

A system, method, and computer program product are provided for performing operations on data utilizing a computation module. In use, input data is received at a computation module, utilizing a chassis removably coupled to the computation module. Additionally, one or more operations are performed on the data, utilizing the computation module. Further, output data is provided from the computation module, utilizing the chassis.

### FIELD OF THE INVENTION

The present invention relates to computer system configuration, and more particularly to computer system modularization.

### BACKGROUND

Computer systems have become essential to many aspects of modern day life. For example, individuals use computer systems to conduct business, communicate with their friends, maintain their personal finances, etc. However, current techniques for designing and implementing computer systems have been associated with various limitations.

For example, current computer systems have a finite life cycle with a limited or nonexistent upgrade path. For instance, if an individual would like to upgrade their existing laptop computer to a laptop computer with a larger screen, they may have to purchase an entirely new laptop computer. Further, if the individual purchases a tablet computer in addition to their laptop computer, their tablet computer may have a hardware system that is completely distinct from their laptop computer.

There is thus a need for addressing these and/or other issues associated with the prior art.

### SUMMARY

A system, method, and computer program product are provided for performing operations on data utilizing a computation module. In use, input data is received at a computation module, utilizing a chassis removably coupled to the computation module. Additionally, one or more operations are performed on the data, utilizing the computation module. Further, output data is provided from the computation module, utilizing the chassis.

### BRIEF DESCRIPTION OF THE DRAWINGS

FIG. 1 shows a method for performing operations on data utilizing a computation module, in accordance with one embodiment.

FIG. 2 shows an exemplary computation module system, in accordance with another embodiment.

FIG. 3 shows an exemplary computation module, in accordance with yet another embodiment.

FIG. 4 shows exemplary computation module hardware, in accordance with yet another embodiment.

FIG. 5 shows an exemplary case for computation module hardware, in accordance with yet another embodiment.

FIG. 6 shows an exemplary system that is supplemented by a computation module, in accordance with yet another embodiment.

FIG. 7 shows an exemplary online marketplace for purchasing a computation module and chassis, in accordance with yet another embodiment.

FIG. 8 illustrates an exemplary system in which the various architecture and/or functionality of the various previous embodiments may be implemented.

### DETAILED DESCRIPTION

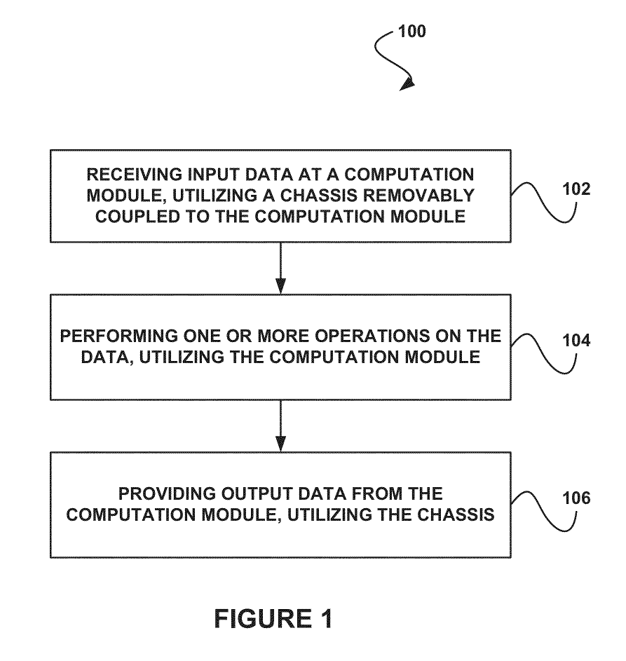

FIG. 1 shows a method 100 for performing operations on data utilizing a computation module, in accordance with one embodiment. As shown in operation 102, input data is received at a computation module, utilizing a chassis removably coupled to the computation module. In one embodiment, the chassis may include a data entry element. For example, the chassis may include one or more of a keyboard, a mouse, a touch screen, a microphone, a digital camera, a network connection (e.g., a wired network connection, a wireless network connection), a bus connection (e.g., a universal serial bus (USB) connection, etc.), etc. In another embodiment, the chassis may include a data output element. For example, the chassis may include one or more of a screen, speakers, tactile output, etc.

Additionally, in one embodiment, the chassis may include a traditional computer system form factor (e.g., platform, etc.) with one or more data processing elements (e.g., a central processing unit (CPU), a graphics processing unit (GPU), etc.) and one or more storage elements (e.g., a hard disk drive (HDD), etc.). For example, the chassis may include a notebook computer, a netbook, computer, a desktop computer, an all in one (AIO) computer, etc. In another embodiment, the chassis may include the traditional computer system form factor, without the computing capability provided by the traditional computer system form factor (e.g., without one or more data processing elements, etc.). For example, the chassis may include one or more data entry elements and one or more data output elements, but may not include one or more data processing elements.

Further, in one embodiment, the computation module may include any module capable of performing one or more computations on data. In another embodiment, the computation module may include one or more processors. For example, the computation module may include a central processing unit (CPU), a graphics processing unit (GPU), etc. In yet another embodiment, the computation module may include one or more integrated circuits. For example, the computation module may include a system on a chip (SOC) that integrates one or more computing components (e.g., a microcontroller, memory, timing sources, timers, interfaces, regulators, etc.) into a single chip. In yet another embodiment, the computation module may include a data communications element (e.g., a wireless network interface, a wired network interface, a Bluetooth© interface, etc.).

Further still, in one embodiment, the chassis may be removably coupled to the computation module through one or more connections, interfaces, etc. For example, the computation module may include one or more hardware interfaces, software interfaces, etc. For instance, the computation module may include a connector for coupling the computation module to the chassis. In another embodiment, the connector may include a proprietary connector. In still another embodiment, the connector may include a plurality of pins, where a predetermined number of pins are used for display purposes. For example, a predetermined number of pins of the connector may be dedicated to a bi-directional display connection.

In another embodiment, a predetermined number of pins of the connector may be used for data transfer purposes. For example, a predetermined number of pins of the connector may be dedicated to a bi-directional data connection. In yet another embodiment, the computation module may be coupled to an external portion of the chassis. For example, the computation module may be coupled to the chassis using a dock or other connector located on the outside of the chassis. In another embodiment, the computation module may be coupled to an internal portion of the chassis. For example, the computation module may be placed within a cavity of the chassis and may be coupled to the chassis using an internal connector located within the chassis.

Also, in one embodiment, one or more security measures may be included within the computation module. For example, the computation module may include a locking platform. In another embodiment, the locking platform may include a hardware lock, a software lock, etc. For example, a hardware lock may be implemented within the computation module, and such hardware lock may require a hardware key (e.g., a key contained within a universal serial bus (USB) device, etc.) for the computation module to operate. In yet another embodiment, a predetermined number of pins of a connector may be used for security purposes. For example, a predetermined number of pins of the connector may be dedicated to a locking platform of the computation module.

Additionally, in one embodiment, one or more data storage elements may be included within the computation module. For example, the computation module may contain a local storage device (e.g., a hard disk drive (HDD), a flash memory drive, random access memory (RAM), etc.). In another embodiment, one or more of the data storage elements may store a software operating system, personal data (e.g., data associated with an owner of the computation module), etc.

Further, in another embodiment, the input data may be received at the computation module through one or more data entry elements of the chassis. For example, a user may provide the input data, utilizing the one or more data entry elements of the chassis (e.g., by typing on a keyboard or touch screen of the chassis, plugging a device such as a removable flash memory-based hard drive into the chassis, etc.). In another example, the input data may be received at the computation module utilizing one or more data connections. For example, the input data may be received by the computation module through a network connection of the chassis (e.g., a wired network connection, a wireless network connection, etc.), a data storage connection of the chassis (e.g., a connection to a hard disk drive of the chassis, etc.), etc.

Further still, as shown in operation 104, one or more operations are performed on the data, utilizing the computation module. In one embodiment, the data may be stored within the computation module. For example, the data may be stored within a data storage element of the computation module. In another embodiment, the data may be processed by an application of the computation module (e.g., an application stored within a data storage element of the computation module and run utilizing one or more processors of the computation module). Of course, however, any type of operation may be performed on the data, utilizing the computation module.

Also, in one embodiment, the one or more operations may be performed on the data only if criteria associated with one or more security measures included within the computation module are met. For example, the one or more operations may be performed only if a hardware key is connected to the computation module, if an encryption key is verified by software running on the computation module, etc.

Further, in one embodiment, the computation module may supplement one or more elements of the chassis during the performing of the one or more operations. In another embodiment, the chassis may supplement one or more elements of the computation module during the performing of the one or more operations. For example, the input data may represent a portion of a larger set of data input to the chassis, where the input data is offloaded from the chassis to the computation module. For instance, a portion of the processing may be performed by a processor on the chassis, and another portion of the processing may be performed by the computation module. In yet another embodiment, the graphics processing may be performed exclusively by a dGPU on the chassis or by a combination of shared processing between the dGPU on the chassis and the GPU within the computation module (e.g., utilizing SLI® technology, etc.). For example, one or more of software algorithms and dedicated scalability logic may be used withinin the dGPU on the chassis and the GPU within the computation module to enable shared processing. In another embodiment, the processing may include one or more of graphics processing, network processing, sound processing, general processing, etc.

In addition, as shown in operation 106, output data is provided from the computation module, utilizing the chassis. In one embodiment, the output data may be provided as output of an application running within the computation module. In another embodiment, the output data may be data stored within a storage component of the computation module that is retrieved. In yet another embodiment, the output data may be processed by one or more processors of the computation module. For example, the output data may include graphics data that is processed by a graphics processing unit (GPU) of the computation module.

In one embodiment, the output data may be provided from the computation module through one or more data output elements of the chassis. For example, the output data may include video data and such data may be transferred from the computation module to a display of the chassis (e,g., utilizing a connection between the computation module and the chassis). In another example, the output data may include audio data and such data may be transferred from the computation module to one or more speakers of the chassis. In yet another example, the output data may include packetized data (e.g., data packets, etc.), and such data may be transferred from the computation module to a network connection of the chassis,

In this way, the computation module may act as a portable computer without a display or tactile interface, and may obtain both a display and tactile interface from the chassis to which it is removably coupled. Additionally, an owner of the computation module may purchase a plurality of chasses and may connect to a different chassis when desired for example, the user may connect the computation module to a desktop computer chassis while working with the computation module at home, and may connect the computation module to a laptop computer chassis while working with the computation module away from home.

More illustrative information will now be set forth regarding various optional architectures and features with which the foregoing framework may or may not be implemented, per the desires of the user. It should be strongly noted that the following information is set forth for illustrative purposes and should not be construed as limiting in any manner. Any of the following features may be optionally incorporated with or without the exclusion of other features described.

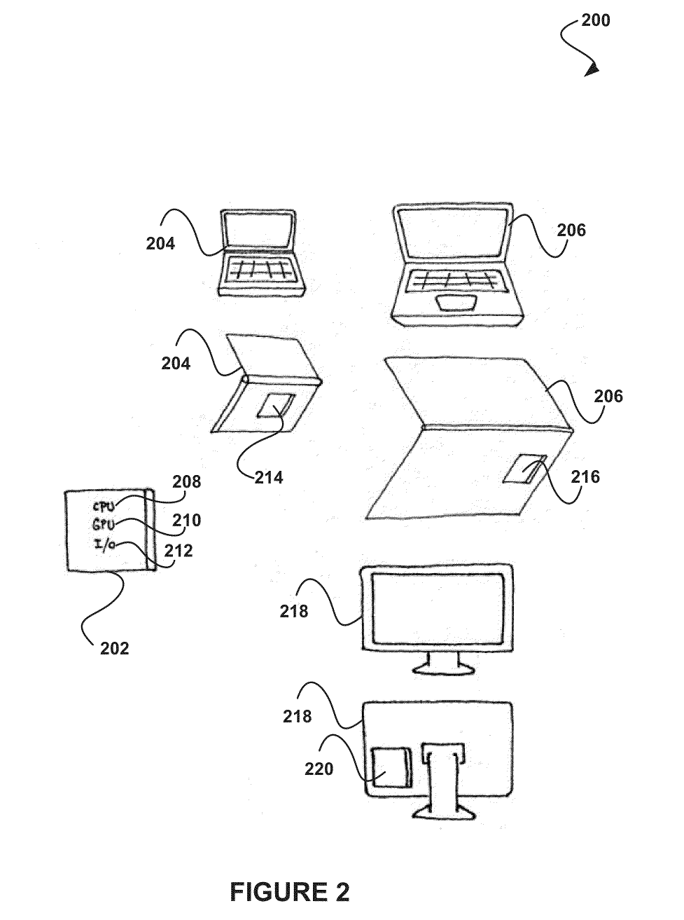

FIG. 2 shows an exemplary computation module system 200, in accordance with another embodiment. As an option, the system 200 may be carried out in the context of the functionality of FIG. 1. Of course, however, the system 200 may be implemented in any desired environment. It should also be noted that the aforementioned definitions may apply during the present description.

As shown, the system 200 includes a computation module 202, as well as a first computer chassis 204, a second computer chassis 206, and a third computer chassis 218. In one embodiment, each of the computation module 202, the first computer chassis 204, the second computer chassis 206, and the third computer chassis 218 may have their own unique identifier. Additionally, the computation module 202 includes a central processing unit 208, a graphics processing unit 210, and a data connection 212. Additionally, the first computer chassis 204, the second computer chassis 206, and the third computer chassis 218 include a connector 214, 216, and 220, respectively. In one embodiment, each connector 214, 216, and 220 may include a proprietary connector (e.g., a connector licensed by a particular manufacturer, company, etc.). In another embodiment, the first computer chassis 204, the second computer chassis 206, and the third computer chassis 218 may each include one or more of a liquid crystal display (LCD), a notebook housing, a keyboard, a power supply and power adapter, etc.

Additionally, in one embodiment, a user may purchase the computation module 202 in conjunction with the first computer chassis 204. For example, the computation module 202 may be coupled to the first computer chassis 204 using the connector 214, and both may be sold as a single unit (e.g., as an ultraportable notebook, etc.). Additionally, in one embodiment, after purchasing the computation module 202 in conjunction with the first computer chassis 204, the user may purchase the second computer chassis 206. For example, the user may purchase a larger notebook chassis with a larger screen.

Further, in another embodiment, the user may uncouple the computation module 202 from the connector 214 of the first computer chassis 204, and may couple the computation module 202 to the connector 216 of the second computer chassis 206. In yet another embodiment, the user may also purchase the third computer chassis 218, may uncouple (he computation module 202 from the connector 216 of the second computer chassis 206, and may couple the computation module 202 to the connector 220 of the third computer chassis 218. In one embodiment, the computation module 202 may be powered off before de-coupling the computation module 202 from one of the connectors 214, 216, and 220. In another embodiment, the computation module 202 may remain powered on while de-coupling the computation module 202 from one of the connectors 214, 216, and 220 (e.g., by utilizing a portable power supply such as a battery inside the computation module 202, etc.).

Also, although chassis 204, 206, and 218 have been shown, it should be noted that the chassis can include any device capable of connecting with the computation module 202. Table 1 illustrates examples of possible chasses, in accordance with one embodiment. Of course, it should be noted that the chasses shown in Table 1 are set forth for illustrative purposes only, and thus should not be construed as limiting in any manner.

TABLE 1
Potential platform implementations for computation module:

Consumer PCs

Portable PC

Netbook
“Ultrabook”
Notebook

Notebook docking stations

Tablet
PDA (personal digital assistant)

Desktop PC

All-in-one
Traditional PC “tower” or workstation
Small-form-factor

Servers (rackmount)
NAS (network-attached storage)
Table PC (ie: Microsoft Surface ©)
External Hard Drive

Consumer Electronics

Televisions
Video game consoles (Xbox ©, Playstation ©, etc.)
Blu-ray players
AV Receivers
Digital Media Player (ie: AppleTV ©, Roku ©, etc.)
Telephone (video conferencing, IP Phones, etc.)
Cellphones
Camcorders/Video cameras
Digital Cameras
Wireless Routers
Electronic picture frame
Alarm clock
Behind-glass system (ie: bathroom mirror)

Military applications

UAV or drone control
Airplane heads-up display
Munitions control and guidance (land, air, sea munitions)
Military Vehicles (see below)

Vehicles (land, air, sea)

Electronic dashboard/console
GPS
In-vehicle entertainment

In this way, the computation module 202 may be used in any of the first computer chassis 204, the second computer chassis 206, or the third computer chassis 218 by simply coupling the computation module 202 to the desired chassis. In one embodiment, given the flexibility the computation module 202 allows since it may only require a chassis that features the connector 214, 216, and 220, there may be no limitations to the different platforms that the computation module 202 can be coupled with. For example, computer monitors, high definition televisions (HDTVs), and other devices may include the computation module 202 as a “built-in” computing system simply by integrating a connector and appropriate power supply. Additionally, since the computation module 202 may connect with any chassis that features the appropriate connector, a user of the computation module 202 may have the flexibility to leverage the computation module 202 in a wide variety of different designs to best suit their usage model for a given time.

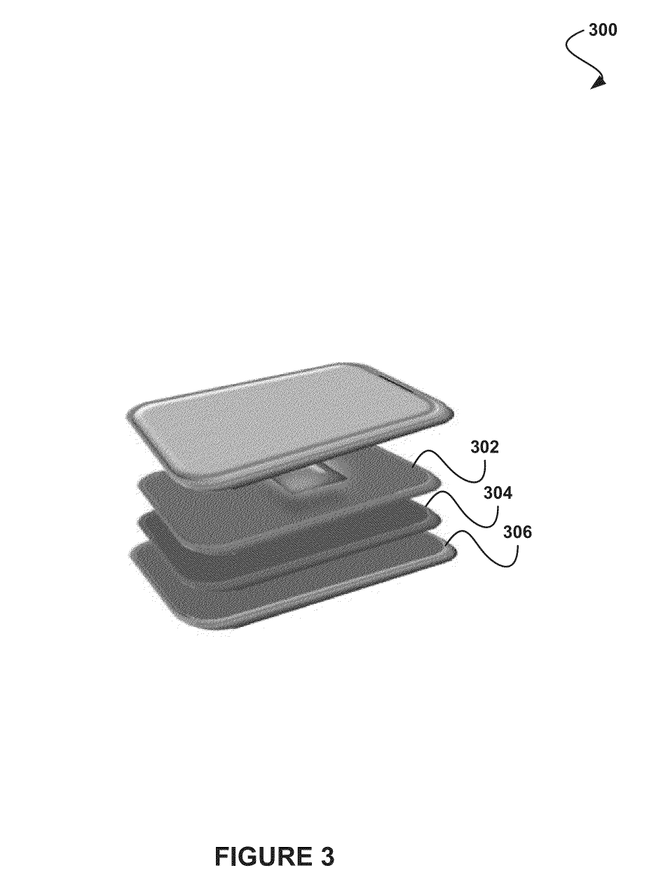

FIG. 3 shows an exemplary computation module 300, in accordance with another embodiment. As an option, the present computation module 300 may be carried out in the context of the functionality of FIGS. 1 and 2. Of course, however, the computation module 300 may be implemented in any desired environment. It should also be noted that the aforementioned definitions may apply during the present description.

As shown, the computation module 300 includes a system on a chip (SOC) 302. In one embodiment, the SOC 302 may include a central processing unit (CPU), a graphics processing unit (GPU), an input/output mechanism, etc. Additionally, the computation module 300 includes a local storage element 304. In one embodiment, the :local storage element 304 may include a hard disk drive (HDD), a flash-based disk drive, etc. In another embodiment, the local storage element 304 may store an operating system, personal files, etc.

Additionally, the computation module 300 includes a security element 306. In one embodiment, the security element 306 may include a proprietary connector. For example, the security element 306 may include a hardware lock (e.g., a proprietary connector) that locks the computation module 300 to a particular manufacturer, user, etc. In another embodiment, the security element 306 may include a software lock (e.g., password protection software), and may use link IDs for everything within the computation module platform. In this way, data within the computation module 300 may be secured.

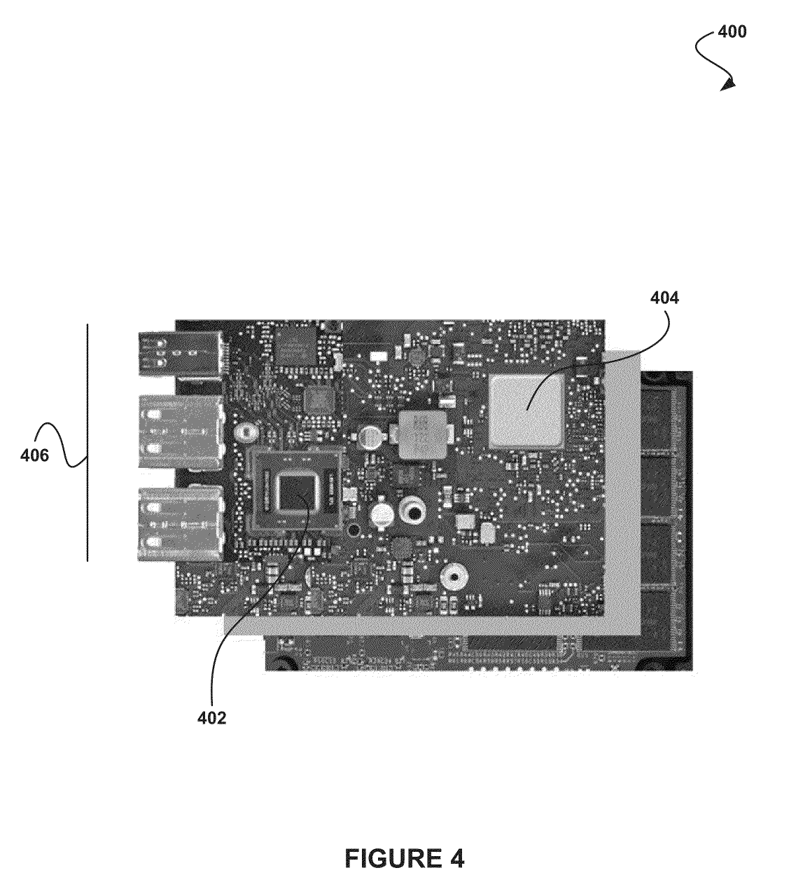

FIG. 4 shows exemplary computation module hardware 400, in accordance with another embodiment. As an option, the present hardware 400 may be carried out in the context of the functionality of FIGS. 1-3. Of course, however, the hardware 400 may be implemented in any desired environment. It should also be noted that the aforementioned definitions may apply during the present description.

As shown, the computation module hardware 400 includes a CPU 402 and a GPU 404. Additionally, the computation module hardware 400 includes a proprietary connector 406. In one embodiment, the proprietary connector 406 may include a predetermined number of pins that may be dedicated to displaying data of the computation module. For example, the proprietary connector 406 may include a predetermined number of pins that may be dedicated to a bi-directional display connection.

Additionally, in one embodiment, the proprietary connector 406 may include a predetermined number of pins that may be dedicated to the transfer of data to and from the computation module. For example, the proprietary connector 406 may include a predetermined number of pins that may be dedicated to a bi-directional data connection. In another embodiment, the proprietary connector 406 may include a predetermined number of pins that may be dedicated to the security of the computation module. For example, the proprietary connector 406 may include a predetermined number of pins that may be dedicated to a locking platform of the computation module.

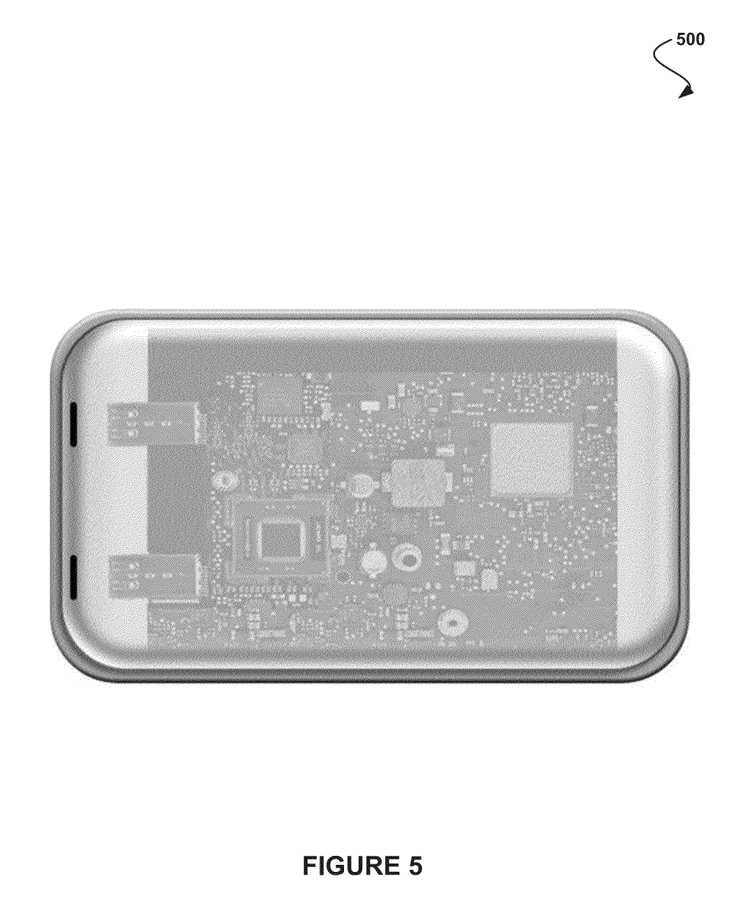

In another example, the locking platform may be associated with a USB device. For example, a USB device with a software key stored on the USB device may have to be connected to the proprietary connector 406 in order for the computation module to operate. In another embodiment, the proprietary connector 406 may include a licensed connector (e.g., a connector licensed to a particular manufacturer, etc.). Further, FIG. 5 shows an exemplary case 500 for the computation module hardware 400. In one embodiment, the case 500 may be made of metal, plastic, or any other material (e.g., radio frequency-shielding material, etc.).

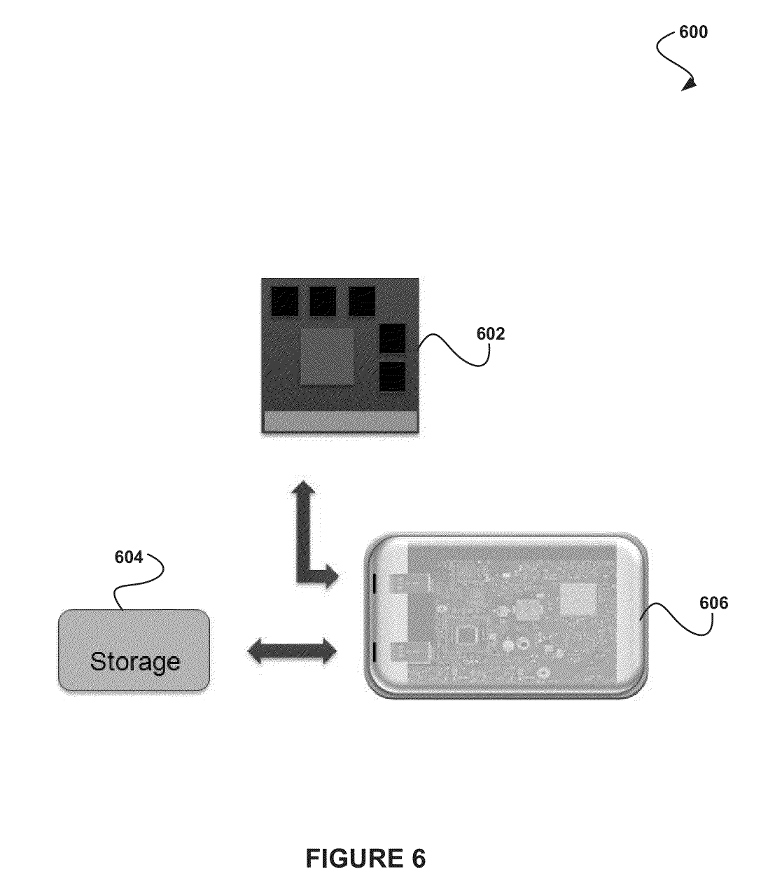

FIG. 6 shows an exemplary system 600 that is supplemented by a computation module, in accordance with another embodiment. As an option, the present system 600 may be carried out in the context of the functionality of FIGS. 1-5. Of course, however, the system 600 may be implemented in any desired environment. It should also be noted that the aforementioned definitions may apply during the present description.

As shown, the system 600 includes an existing GPU 602 and storage device 604. In one embodiment, the GPU 602 may include a discrete GPU (dGPU), and the system may include a dGPU platform (e.g., an all in one (AIO) system, a small form factor gaming system, a notebook docking station, etc.). In another embodiment, the GPU 602 and storage device 604 may be included within a standalone computing device (e.g., a personal computer, an integrated computing system, etc.). Additionally, the GPU 602 and storage device 604 are supplemented by a computation module 606 coupled to both the GPU 602 and storage device 604. In one embodiment, the computation module 606 may be coupled to a standalone computing device (e.g., utilizing a proprietary connector), where the standalone computing device contains the GPU 602 and storage device 604.

Additionally, in one embodiment, the GPU 602 may attach to the computation module 606 via a bi-directional port (e.g., a mobile PCI express module (MXM), a Thunderbolt connection, etc.). In this way, the GPU 602 may assist the computation module 606 in processing (e.g., by offloading some processing duties from the computation module 606 ). Additionally, the GPU 602 may override the computation module 606. For example, the GPU 602 may perform all processing duties previously performed by the computation module 606. In this way, the GPU 602 may supplement the computation module 606, which may result in increased performance of the system 600.

Further, in one embodiment, the computation module 606 may attach to the storage device 604 via a bi-directional data connection. In another embodiment, data may be transferred between the computation module 606 and the storage device 604. In another embodiment, the computation module 606 may perform all or some storage duties previously performed by the storage device 604. In this way, the computation module 606 may supplement the storage device 604, which may improve the storage within the system 600.

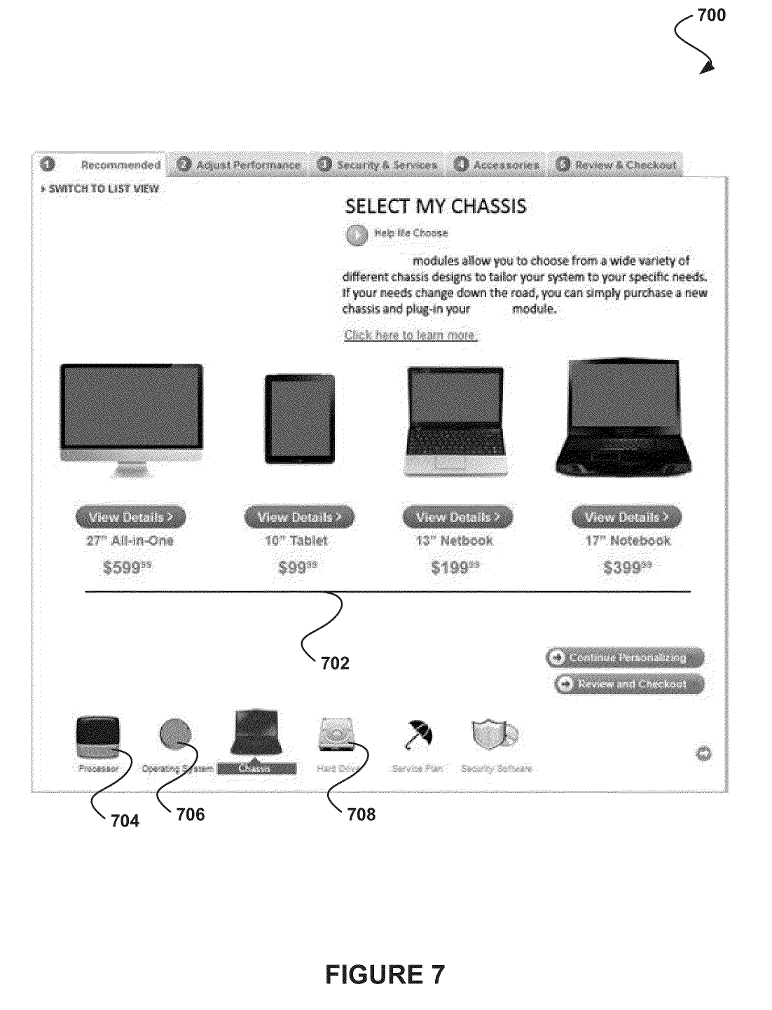

FIG. 7 shows an exemplary online marketplace 700 for purchasing a computation module and chassis, in accordance with another embodiment. As an option, the present marketplace 700 may be carried out in the context of the functionality of FIGS. 1-6. Of course, however, the marketplace 700 may be implemented in any desired environment. It should also be noted that the aforementioned definitions may apply during the present description.

As shown, the marketplace 700 includes a selection of available chasses 702 from which to purchase. Additionally, the marketplace 700 includes a processor selection icon 704, an operating system selection icon 706, and a hard drive selection icon 708. In one embodiment, a user may configure a processor, operating system, and hard drive for a computation module using the processor selection icon 704, operating system selection icon 706, and hard drive selection icon 708, respectively. Additionally, the user may select one or more chasses from the selection of available chasses 702, where the configured computation module may be removably coupled to the selected chasses.

In this way, a socketed personal computer platform may be created which may be leveraged across a wide variety of chassis designs the best suit a given application or usage. Additionally, core personal computer components may be present on a proprietary card design and may be swapped between chassis. Further, a wide variety of different chasses (e.g., notebook, desktop, automotive, etc.) may be provided, and television and other display vendors may offer devices with either the computation module included or available as a separate module to update displays in the future.

Also, multiple inexpensive empty chassis may be purchased for use with a single computation module, instead of purchasing multiple expensive independent computer systems. Further still, personal information stored within the computation module may be secured within the computation module and may be moved with the computation module from chassis to chassis. In addition, the product life cycle of the computation module is separated from the product life cycle of the chassis—a user may upgrade the computation module (e.g., to a higher performance category, etc,) without having to upgrade chasses, and can upgrade one or more chasses without having to upgrade the computation module.

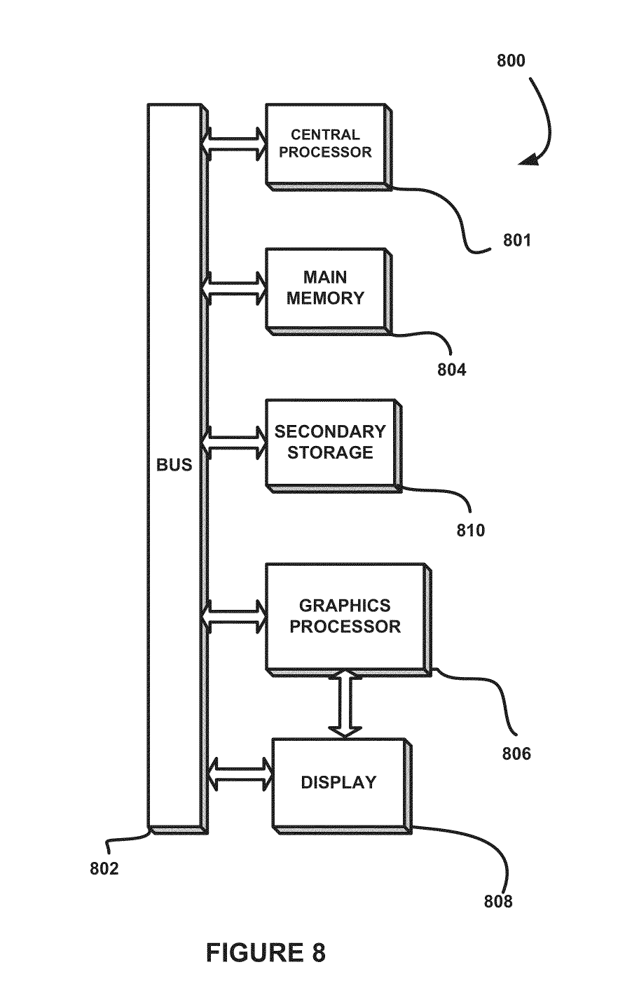

FIG. 8 illustrates an exemplary system 800 in which the various architecture and/or functionality of the various previous embodiments may be implemented. As shown, a system 800 is provided including at least one host processor 801 which is connected to a communication bus 802. The system 800 also includes a main memory 804. Control logic (software) and data are stored in the main memory 804 which may take the form of random access memory (RAM).

The system 800 also includes a graphics processor 806 and a display 808, i.e. a computer monitor. In one embodiment, the graphics processor 806 may include a plurality of shader modules, a rasterization module, etc. Each of the foregoing modules may even be situated on a single semiconductor platform to form a graphics processing unit (GPU).

In the present description, a single semiconductor platform may refer to a sole unitary semiconductor-based integrated circuit or chip. It should be noted that the term single semiconductor platform may also refer to multi--chip modules with increased connectivity which simulate on-chip operation, and make substantial improvements over utilizing a conventional central processing unit (CPU) and bus implementation. Of course, the various modules may also be situated separately or in various combinations of semiconductor platforms per the desires of the user,

The system 800 may also include a secondary storage 810. The secondary storage 810 includes, for example, a hard disk drive and/or a removable storage drive, representing a floppy disk drive, a magnetic tape drive, a compact disk drive, etc. The removable storage drive reads from and/or writes to a removable storage unit in a well known manner.

Computer programs, or computer control logic algorithms, may be stored in the main memory 804 and/or the secondary storage 810. Such computer programs, when executed, enable the system 800 to perform various functions. Memory 804, storage 810 and/or any other storage are possible examples of computer-readable media.

In one embodiment, the architecture and/or functionality of the various previous figures may be implemented in the context of the host processor 801, graphics processor 806, an integrated circuit (not shown) that is capable of at least a portion of the capabilities of both the host processor 801 and the graphics processor 806, a chipset (i.e. a group of integrated circuits designed to work and sold as a unit for performing related functions, etc.), and/or any other integrated circuit for that matter.

Still yet, the architecture and/or functionality of the various previous figures may be implemented in the context of a general computer system, a circuit board system, a game console system dedicated for entertainment purposes, an application-specific system, and/or any other desired system. For example, the system 800 may take the form of a desktop computer, laptop computer, and/or any other type of logic. Still yet, the system 800 may take the form of various other devices m including, but not limited to a personal digital assistant (IDA) device, a mobile phone device, a television, etc.

Further, while not shown, the system 800 may be coupled to a network [e.g. a telecommunications network, local area network (LAN), wireless network, wide area network (WAN) such as the Internet, peer-to-peer network, cable network, etc.) for communication purposes.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

What is claimed is:

1. A method, comprising:
receiving input data at a computation module, utilizing a chassis removably coupled to the computation module;
performing one or more operations on the data, utilizing the computation module; and
providing output data from the computation module, utilizing the chassis.

2. The method of claim 1, wherein the chassis includes a computer system form factor with one or more data processing elements.

3. The method of claim 1, wherein the chassis includes a computer system form factor without one or more data processing elements.

4. The method of claim 1, wherein the computation module includes a system on a chip (SOC).

5. The method of claim 1, wherein the computation module includes a connector for coupling the computation module to the chassis.

6. The method of claim 1, wherein the computation module includes a locking platform.

7. The method of claim 6, wherein the locking platform includes one or more of a hardware lock and a software lock.

8. The method of claim 1, wherein the input data is received at the computation module through one or more data entry elements of the chassis.

9. The method of claim 1, wherein the one or more operations are performed on the data only if criteria associated with one or more security measures included within the computation module are met.

10. The method of claim 1, wherein the output data is provided from the computation module through one or more data output elements of the chassis.

11. The method of claim 1, wherein the computation module supplements one or more elements of the chassis during the performing of the one or more operations.

12. The method of claim 11, wherein the input data represents a portion of a larger set of data input to the chassis, where the input data is offloaded from the chassis to the computation module.

13. The method of claim 1, wherein a portion of the processing is performed by a processor on the chassis, and another portion of the processing is performed by the computation module.

14. The method of claim 1, wherein the processing includes one or more of graphics processing, network processing, and sound processing.

15. The method of claim 1, wherein a hardware lock is implemented within the computation module, and such hardware lock requires a key contained within a universal serial bus (USB) device for the computation module to operate.

16. The method of claim 1, wherein the computation module is placed within a cavity of the chassis and is coupled to the chassis using an internal connector located within the chassis.

17. The method of claim 5, wherein a predetermined number of pins of the connector are dedicated to a bi-directional display connection, a predetermined number of pins of the connector are dedicated to a bi-directional data connection, and a predetermined number of pins of the connector are dedicated to a locking platform of the computation module.

18. A computer program product embodied on a computer readable medium, comprising:
code for receiving input data at a computation module, utilizing a chassis removably coupled to the computation module;
code for performing one or more operations on the data, utilizing the computation module; and
code for providing output data from the computation module, utilizing the chassis.

19. A system, comprising:
a computation module removably coupled to a chassis, the computation module for receiving input data utilizing the chassis, performing one or more operations on the data, and providing output data, utilizing the chassis.

20. The system of claim 19, wherein the computation module includes memory coupled to a processor via a bus.
